(19) United States
(12) Patent Application Publication
(10) Pub. No.: US 2010/0195840 A1
(43) Pub. Date: Aug. 5, 2010

(54) REAL-TIME CONTINUOUS DIGITAL CONTROL OF PARAMETERS AND SETTINGS OF ANALOGUE SOUND EFFECTS

(76) Inventor: Massimiliano Ciccone, Leinden (NL)

Correspondence Address: YOUNG & THOMPSON, 209 Madison Street, Suite 500, Alexandria, VA, 22314, US

(21) Appl. No.: 12/663,372

(22) PCT Filed: Apr. 10, 2008
(86) PCT No.: PCT/EP2008/054321

§ 371 Date: Apr. 20, 2010

(30) Foreign Application Priority Data
Apr. 17, 2007 (EP) 07075287.8

(51) Int. Cl. H03G 3/00; G06F 17/00

(52) U.S. Cl. 381/61; 700/94

(57) ABSTRACT

The present invention provides an apparatus comprising digital means adapted to synthesise a digital waveform; conditioning unit means adapted to convert the digital waveform into an analogue waveform; and modulating means adapted to an analogue sound-carrying signal and said analogue waveform, and to modulate said analogue sound-carrying signal using the analogue waveform. In another aspect of the present invention there is provided a method for digitally controlling, continuously and in real-time, at least one analogue sound effect applied to an analogue sound-carrying signal from a musical source, which comprises the steps of synthesising a digital waveform; converting said digital waveform into an analogue waveform; modulating an analogue sound-carrying signal using said analogue waveform as modulating signal.

### FIELD OF THE INVENTION

The invention relates to an apparatus and to a method for controlling an analogue sound effect device. The invention also relates to a sound effect apparatus for applying a number of sound effects to an input tone.

The invention is targeted to musicians using apparatuses to modulate, distort, condition or amplify the music tone of their instruments, microphones or other sources in live, studio or private performances. These apparatuses are generally known as sound effects. Commonly used effects include compression, distortion, “wah-wah” and other filters, flanger, chorus, delay, phaser, etc.

### BACKGROUND ART

Traditionally, sound effects can be divided in two categories: analogue effects and digital effects (e.g., using a digital signal processor or DSP).

As depicted in FIG. 1, conventional analogue effects are individually enclosed in a unit 100, which may comprise an on/off switch 110, preferably operable by foot pedal, one or more inputs 120, for connecting the unit to a musical signal source(s), one or more outputs 130 to extract the processed music tone, and a power supply input 140. Further, the unit generally comprises manually operable controls 150 to adjust the amount of the effect applied to the input signal, various parameters associated with each effect, and the volume of the output signal. These effects are sometimes known as “pedals”, or “stomp boxes” by musicians and in particular by guitarists.

While analogue effects are generally seen as providing the best sound quality, they also have shortcomings. In analogue effects, the effect's parameters are conventionally set by means of rotating analogue controls, switches and/or sliders. This makes it impossible to store and quickly recall a particular combination of effect's parameters—i.e., the “sound” obtained—once it has been modified in order to produce a different sound, since the position of these controls cannot be stored and must be remembered exactly.

It is common for a musician to use one or more effects (e.g., compressor and chorus) in order to obtain the required sound for the song s/he is playing. Many of these units must therefore be cascaded. Doing this, however, degrades the sound quality, mainly as a result of impedance mismatching effects and of the noise of the cascaded units. This problem arises even when the units are in bypass mode and increases with the number of units connected in series. In addition, the musician now faces the problems of remembering exactly and having to manually (re)set a multiplicity of parameters on a multiplicity of effects, by means of said rotating controls, switches, and/or sliders, which is obviously a great nuisance, especially during live performances.

A commonly adopted solution is to increase the number of “pedals” available so as to leave each effect preset for a certain sound and use another unit, producing the same effect (e.g., tremolo) but with different parameters, for a different sound (e.g., in a different song). While obviating the specific problem described above, this solution has the disadvantage of being expensive, since it multiplies the number of effects a musician must buy, and highly ineffective, since many of these effects will be switched off during most of the performance, and will only be used once. Besides, in order to change sound at each change of song—and often even for different phrases of the same song—the musician has to switch on or off a number of effects by acting on the effects' foot-operable switches 100 (FIG. 1). This process of reconfiguring the effect chain is distracting and error-prone, since it is easy to inadvertently switch in or out the wrong effect, thereby producing the wrong sound.

A further problem with analogue effects can be understood as follows. In general terms, a traditional analogue effect manipulates the signal coming from the music instrument according to the status of its internal oscillator (VCO). This oscillator produces a carrier frequency with a maximum frequency below 20 Hz. The user can change the amplitude and the frequency of this carrier frequency in order to produce the desired effect. Due, inter alia, to cost limitations, the analogue VCO is quite simple and can generate only a few different, well-known time-symmetrical functions, such as sine, rect (rectangular), trig (triangle), saw (saw tooth). The range of modulation functions that can be applied to the sound of the instrument is therefore limited, directly restricting the musician's creative scope.

Owing to the increased availability of computing resources, digital effects have gained popularity in recent years, partly in an attempt to solve some of the problems described above. These effects provide digital setting and storing of (combination of) effects' settings, along with their easy and quick retrieval. Furthermore, by replacing analogue sound processing circuitry with one or more digital signal processing (DSP) units, many effects can be simultaneously produced by the same programmable unit, thereby reducing the number of units required for a performance. Additionally, integrated digital multi-effect units are not affected by impedance mismatching.

However, DSP units powerful enough to replace a conspicuous number of analogue effects are expensive. They also present a more serious drawback: the digitisation of the musical signal by the DSP, and the subsequent re-conversion into an analogue signal for amplification, so degrades the signal as to make it impossible to achieve the same quality of sound afforded by analogue effects. Quantisation noise is one of the biggest problems affecting sound digital signal processing and it is commonly acknowledged that the resulting sound lacks definition and transparency. The degradation becomes particularly evident when the input signal is much smaller than the dynamic of the analogue-to-digital converter, which is commonly the case for signals coming from electric or electrified guitars. All this makes digital effects unsuitable for e.g., professional musicians.

U.K. patent GB2405987 sought to solve some of the problems mentioned above by providing a switch-matrix for externally connected effects, capable of switching in or out a number of effects in just one switching action. GB2405987 also sought to minimise the impedance mismatch problem by bypassing the effects not in use. The application however still relies on external effects and does not solve the problem of the cumbersome on-the-fly reconfiguration or their parameters. The musician is thus still left on one hand with the need of purchasing more effects than s/he will need at any given time during the performance, and on the other with the impossibility of modifying the effects' settings in any way during a performance. The solution proposed is therefore not cost-effective. Also the impedance mismatch is only minimised to the strictly necessary minimum but not obviated altogether, since the active external effects are still connected in series. It must be kept in mind that “pedals”, or analogue effects, are generally designed to be operated singularly (i.e., between a musical instrument, connected to their input, and an amplifier, connected to their output), and not in combination (i.e., daisy-chained) with other “pedals”. Their input and output circuitries are therefore not designed to match—and cooperate with—those of other “pedals” but rather with those of instruments and/or amplifiers, thus resulting in impedance mismatching. The resulting sound-impairing effect increases with the number of effects daisy-chained.

U.S. Pat. No. 5,583,308 introduces the idea of digitally controlling analogue effects. This document however describes a method for teaching how to play and the digital controls therein arc used only in order to modify, and store, the effects' parameters so as to match those of a pre-recorded sound, while said pre-recorded sound is being played (parameters are stored in the unused fields of the CD). In U.S. Pat. No. 5,583,308, the parameters of the analogue effects are modified using wiper resistors, that is, a digital potentiometer. The first problem is that the wiper resistors cannot be continuously adjusted because they are slow to respond and generate noise (glitches) each time they are adjusted, thereby affecting the sound quality. Also digital potentiometers are slow to adjust and are only suitable for controlling signals or parameters that need adjusting only rarely—that is, those that need be adjusted between songs. The device in U.S. Pat. No. 5,583,308 is thus not suitable to operate on parameters dynamically adjustable in real-time and does not foresee the possibility of giving the musician access to them. The invention is solely concerned with matching a given sound, for didactical purposes, and thus severely limits the creative possibilities of a musician using it.

It would therefore be highly desirable for a musician to have available a machine capable of imparting multiple effects to a sound carrying signal, if this machine could combine the sound quality of analogue effects, and the easy configurability of digital effects, without the shortcomings inherent in either solution.

The present invention overcomes all the problems described with reference to the prior art and provides a number of other advantageous features to musicians.

### DISCLOSURE OF INVENTION

An aspect of the present invention relates to an apparatus for digitally controlling, continuously and in real-time, at least one analogue sound effect. Another aspect of the present invention provides a method for digitally controlling, continuously and in real-time, an analogue sound effect, applied to an analogue sound-carrying signal.

An aspect of the present invention provides an apparatus comprising digital means adapted to synthesise a digital waveform; conditioning unit means adapted to convert the digital waveform into an analogue waveform; and modulating means adapted to receive the analogue waveform and an analogue sound-carrying signal, and to modulate said, analogue sound-carrying signal using said analogue waveform.

In another aspect of the present invention there is provided a method for digitally controlling, continuously and in real-time, at least one analogue sound effect applied to an electrical analogue sound-carrying signal from a musical source, which comprises the steps of (a) digitally synthesising a sound-modulating waveform; (b) converting said digital waveform into an analogue waveform; (c) modulating an analogue sound-carrying signal using said analogue sound-modulating waveform as modulating signal.

In another aspect of the present invention, an internal oscillator is replaced by a synthesised waveform. This waveform is generated and controlled by a microprocessor, or by other suitable hardware or software means, and then low-pass filtered and interpolated. Due to the low frequency range (<20 Hz) of the synthesised waveform, the process of interpolating (smoothening) the converted signal through a low-pass filter or other suitable circuitry can be performed extremely smoothly so as to render such process inaudible. The inventive solution proposed herein is therefore suitable for professional use.

According to another aspect of the present invention, there is provided a multieffect sound processor (FIG. 2) which contains a number of state-of-the-art analogue effects, whose parameters can be digitally controlled, set, stored, and recalled. The effects' parameters can be controlled in real-time, continuously and dynamically, by the processor itself or by the musician while playing his/her instrument. The sound processor is further provided with input connections 270 for the input signals from signal sources 210, output connections 276 for sending the processed signals to amplifying and/or mixing apparatuses 260, a display 230 and keyboard 223 for operating the digital controls, a number of data communication busses 271 to 274—wired and/or wireless—for allowing the parameters to be stored, set, and recalled, and for allowing the device to be programmed, upgraded and controlled in various inventive ways, which will be described hereafter.

While all the sound processing is carried out analogically, the digital controls enable the effects' settings to be quickly and effectively set, easily stored, recalled and modified on-the-fly by the musician with the help of a configurable controller 220, such as a pedal 222, a wireless remote control 221, a computer 224, or the built-in keyboard 223.

These and other aspect, features and advantages of the invention will become apparent and more readily appreciated from the following detailed description of exemplary embodiments and from the accompanying drawings.

It is to be understood that both the foregoing general description and the following detailed description and drawings are exemplary and explanatory only and are not restrictive of the invention as claimed.

### BRIEF DESCRIPTION OF DRAWINGS

FIG. 1 represents a conventional analogue effect (pedal);

FIG. 2 illustrates an apparatus according to one embodiment of the present invention;

FIG. 3 illustrates a block scheme of the apparatus for digitally controlling analogue effect, according to an embodiment of the present invention;

FIG. 4 illustrates four types of analogue effects and their control schemes;

FIG. 5 illustrates a state machine diagram of the apparatus according to an embodiment of the present invention;

FIG. 6 illustrates a flow chart of the operations of the master processor, according to an embodiment of the present invention;

FIG. 7 illustrates a flow diagram of a method in accordance with an embodiment of the present invention;

FIG. 8 illustrates a flow diagram of a method in accordance with another embodiment of the present invention;

FIG. 9 illustrates a flow diagram of a method in accordance with another embodiment of the present invention.

### BEST MODE FOR CARRYING OUT THE INVENTION

The sound effect apparatus—one of the objects of the present invention—and the method of controlling the sound effect apparatus will be now described in details with reference to the accompanying drawings. Wherever possible, the same reference numbers will be used throughout the drawings to refer to same or like parts, elements or operating steps.

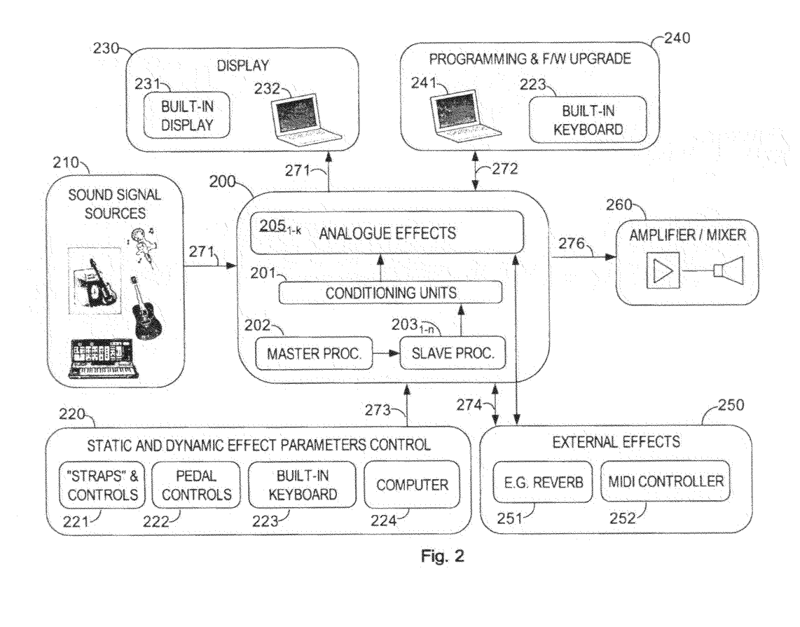

FIG. 2 shows an illustrative block diagram of an analogue sound processor 200, according to the preferred embodiment of the present invention, and its connections. The various elements that compose and/or are connected to the digitally-controlled, analogue sound effect processor 200 have been grouped into functional blocks for a clearer understanding of the novel principles of this invention. The skilled person understands that this subdivision does not necessarily reflect the actual layout of the apparatus.

In FIG. 2 the analogue effect section 205 comprises a number of analogue effects, adapted to modulate and transform various parameters of an input signal tone received by means of a connection 270 from one or more of the sound signal sources 210. Said sources may include electric or electrified guitars, electric pianos, keyboards and synthesisers, microphones, etc.

In the preferred embodiment, a built-in display 231 and/or a computer 232 (the latter connected, for instance, to the machine's USB port) allow the user to select and monitor the (combination of) effects parameters to be modified.

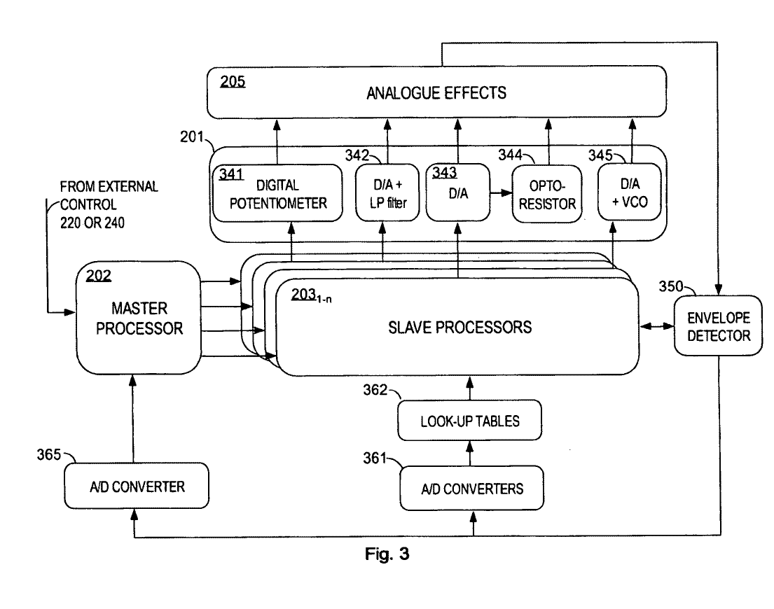

In one exemplary embodiment, the analogue effects in section 205 may include at least one of: compression, tremolo, distortion, panner, one or two formant or “wah-wah” filters, phaser, chorus, flanger, delay, noise gate, and low-noise pre-amplifier. Other embodiments may include a different number or different combinations of the above-mentioned analogue effects. Further, the analogue sound processing section 205 may include an input buffer (not shown), an envelope detector (350, see FIG. 3), and a mixer (not shown), along with a number of in/out connections for music sources 210, optional external effects 250, programming and upgrading devices 240, and external analogue amplification and/or mixing apparatuses 260.

It should be already apparent to those skilled in the art that the layout of FIG. 2 represents a generalised schematic layout and other components may be added or existing components may be removed or modified.

In the preferred embodiment, the analogue effect's parameters (hereafter, the parameters), controlled by the novel method proposed in this invention, may include, depending on the effect: phase, frequency, period, waveform type, waveform amplitude, waveform phase, envelope parameters (e.g., attack and decay), wet/dry ratio (i.e., the ratio between the amount of signal altered by the effect, or wet, and the amount of signal left unaltered, or dry), delay amount, chorus amount, flanger amount, effect on/bypass, etc.

The parameters can be subdivided into static parameters, which are either fixed or rarely (not continuously) modified during the execution of a song, and dynamic parameters, which can be modified, continuously by the processor itself and/or in real-time by the musician during the execution of a song. Examples of static parameters are: the position of the relays (in order to apply or bypass a given effect), wet/dry ratio, relative phases of the effects, distortion's tone and volume, envelope decay and attack, etc, while examples of dynamic ones are: compression ratio and sensitivity, the start frequency and the filter curve of formant filters, panner's phase, tremolo's depth and period, and many more (essentially all the parameters of all the sound-modulating functions). This subdivision is important, since it will be soon clear from this description that the invention not only allows the musician to modify, store and recall static parameters of analogue sound effects more quickly and efficiently than in prior art devices, but also to operate on dynamic parameters of analogue effects in ways which were hitherto not available. The method and the apparatus of this invention allow the musician to effortlessly create a continuously-varying, purely-analogue sound, limited only by his/her creativity.

The invention thus does away with the well-known limitations of analogue effects, insofar as setting, storing, recalling, and continuously modifying their static and dynamic parameters. At the same time, the invention preserves the renowned quality of analogue sound processing, since the sound signal is never digitized, and digital processors are only used in order to greatly improve the controllability of analogue sound effects, so as to provide the musician with new artistic possibilities.

Moreover, since the phases of all the analogue effects are independently but simultaneously controllable by processors 202-203, the relative phases of the effects of any given combination can be adjusted and dynamically controlled (so as to be, for instance, in-phase, in quadrature, in opposition, etc). This enables the effects to musically cooperate in ways which arc simply not possible when using a cascade of separated analogue effects connected by means of cables.

In addition to this, thanks to the integration within one unit of all the analogue effects that a musician needs, the present invention also solves the prior art problem of impedance mismatch in multi-effect chains. On the one hand, all the effects in the sound processor 200 are designed to work together. An input buffer (not shown) takes care of the impedance matching between the instrument and the multi-effect processor 200. Thereafter, all the input and output impedances of the effects in processor 200 are designed, from the onset, for a multi-effect scenario. It is only at the end of the effect's chain that the output impedance is lowered to the level required by the mixer/amplifier 260. On the other hand, since all the parameters, including the impedance, of the analogue effects are controlled by RISC (Reduced Instruction Set Computer) processors 202 and 203, all the possible configurations and combinations of effects have been considered while programming the sound processor 200 and they are stored in a programmable memory. The device 200 shows therefore perfect impedance matching between all the effects, thereby affording superior sonic qualities, compared to prior art solutions.

The core of the invention is represented by the novel way in which the external controls 220, the master RISC processor 202, the slave RISC processors 203, and the analogue effects 205 cooperate. The effect processor 200 may be provided with external controls 220 and 250, connected to the processor 200 through a variety of interfaces (e.g., MIDI, USB, etc.). The external controls 220 and 250 (e.g., an external MIDI controller 252) may be operated by the musician so as to instruct RISC processors 202 and 203 to modify—in real-time—any number of parameters of any number of effects included in sound processor 200, and/or of externally connected effects (e.g., reverb) 251. To make the importance of all this more evident—by way of non-limiting example only—this may mean for the musician the possibility of adapting, in real-time and continuously: the speed of a tremolo according to (micro)variations of the tempo of a song (e.g., for expression purposes); the amount, the type, and the model of the compression applied; the “vowels” produced by the formant filters (or “wah-wah” effect) and the transition between vowels; the amount of chorus or delay applied; etc. It should be completely evident at this point the unique level of creative possibilities offered to musicians by the apparatus and method disclosed in this invention.

Limitations of Analogically-Controlled VCOs

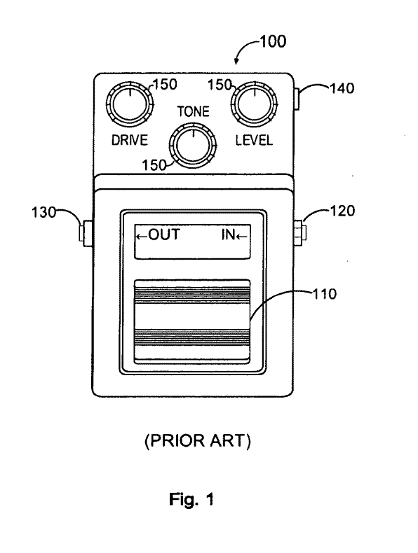

The essence of a sound effect for musical instruments can be described as a lower-frequency waveform modulating a higher-frequency tone (i.e., the input tone from the musical instrument). It is this lower-frequency waveform—controlled by its parameters—that defines the modification of the sound signal operated by the effect and, in certain cases, also the wet/dry ratio. Generally, the lower-frequency waveforms are generated by a voltage-controlled oscillator (VCO). The main shortcomings of analogue effects, though musically superior, originate from the fact that the VCO is both analogically implemented and analogically controlled. The presence of manually-operable rotary or slider controls (see FIG. 1) makes the analogue VCO cumbersome or nearly impossible to control in real-time, while playing, by a musician; as already discussed, it also makes it very complicated to effectively store and recall the effect's parameters. Lastly, but not less importantly, an analogue VCO is inherently unsuitable to generate non time-symmetrical waveforms. Although this will be explained later in greater detail, it can be already intuitively understood that this fact limits the artistic possibilities of a sound effect, since it ultimately restricts the variety of sounds that can be obtained.

This invention does away with analogue VCOs altogether—except in one case where the analogue VCO is controlled by a digital-to-analogue converter (D/A)—and uses the computational speed, the versatility and the store-recall capabilities of microprocessors not to modify the sound but to digitally create, adjust and update in real-time the lower-frequency, sound-modulating waveform.

Referring now to FIG. 2, each one of RISC processors 203 is provided with a number of independent, highly-precise timers, each controlling and driving a suitable conditioning unit 201. Conditioning units 201 are used in this invention to perform a digital-to-analogue conversion, a low-pass filtering and smoothening of a sound-modulating function.

As shown in FIG. 3, in the exemplary embodiment of the present invention, depending on the parameter(s) and on the effect(s) to be controlled, conditioning units 201 may take the form of: a digital potentiometer, a D/A, a D/A with its output connected to the input of a low-pass filter, an opto-resistor controlled by a D/A, or a D/A controlling a VCO.

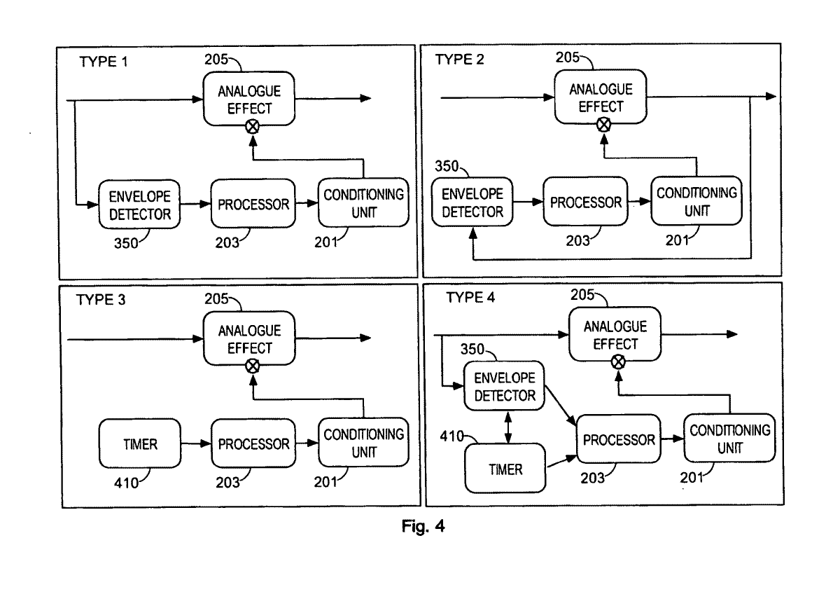

As depicted in FIG. 2, FIG. 3, and FIG. 4, each conditioning unit 201 converts a digitally-synthesised waveform into an analogue-waveform. This analogue waveform is then used to modulate the input sound signal, without any need to digitise the latter. All the limitations of analogue effects are therefore completely removed since the processors can synthesise, store and recall in real-time any waveform, and hence, it is worth repeating here, any combination of effects' parameters and of phase and/or amplitude ratio between any number of effects and their parameters. By way of example only, the max and min volume of the tremolo effect can be controlled so as to have a fixed relationship with the frequency of a formant filter.

While the increased flexibility of this apparatus is already self-evident in its static or semi-static operating mode, it is worth pointing out here that the sound processor 200 can be programmed to dynamically and continuously change the parameters of any number of its effects.

Even more importantly, to further enhance the versatility of sound processor 200, external controls 220 and 252 can be associated to, and configured to control, any number of parameters of any combination of effects, and can be operated in a continuous fashion by the musician to alter the sound during the execution.

Configuration of the Sound Processor: Static Parameters

Referring to FIG. 2, all the parameters of analogue effects 205 are controlled by one of a number n of slave RISC processors 203₁₋ₙ.

In the preferred embodiment, 4 slave RISC processors 203₁ to 203₄ are present. In other embodiments, a reduced or increased number of processors can be used, depending on a trade-off between, inter-alia, power consumption, total cost, number of parameters to be controlled (depending in turn on the number of effects included in processor 200), speed of operation, etc.

Those of ordinary skill in this art will understand that the above-described processors 202 and 203₁₋ₙ could, for instance, be replaced by ordinary (i.e., non RISC) microprocessors, by one single processor, capable of implementing all the functions carried out here by separate processors, by one or more digital signal processor(s) (DSP), by one or more field-programmable arrays (FPGA), by application-specific integrated circuits (ASICs), by an external and/or an onboard computer based system, by a processor-containing system, or other systems that can fetch instruction from a medium and execute the instructions, by software means or any other suitable means.

Slave processors 203₁₋ₙ, are controlled by master processor 202. In the standard operating mode, master processor 202 may receive from one or more of external controls 220, or 252, an instruction to switch in or out—and to modify one or more parameters of—one or more analogue effects 205. Controls 220 and 252 may be operated, for instance, by the musician, by a studio technician, or by sound engineer. Master processor 202 then sends an instruction to the appropriate slave processor(s) 203 to control the relay circuits, enabling the switching into the effect chain of the required analogue effect 205. The relays used to switch in or to bypass an analogue effect may be controlled directly by the RISC processors 203.

As mentioned above, the preferred embodiment of the invention provides a number of controls 221-224 with which the musician can instruct the master RISC processor 202 to modify the configuration of sound processor 200, i.e., the static parameters. Controls 221-224 are exemplified in FIG. 2 by the familiar pedal controls 222, also known as foot controllers (e.g. foot-operated switches and potentiometers), by the processor's built-in keyboard 223, or by a computer 224. Other types of controls may be used without departing from the scope of the present invention. “Strap” controls 221 are, for instance, particular switching devices (which, by way of example only, can take the form of switches or regulators of the types known in the art) that can be located remotely from the sound processor 200, and connected to it through a wired or a wireless link. They may, in particular, be “strapped” onto the musical instrument or onto the musician's clothes, for increased portability, and operated by hand during the performance. Other controls may take the form of external MIDI controllers 252.

Control signals 273 are sent from controls 220 or 252 to master RISC processor 202 in digitally encoded form, using an appropriate number of bits and one or more of the known transmission protocols such as MIDI, USB, wireless USB, Wi-Fi®, etc. These control signals contain instructions addressed to the master processor 202 to change the parameters of effect processor 200.

It is important to understand here that, owing to the novel architecture proposed in the embodiments of this invention, at least 140 parameters of at least 21 analogue effects can be stored, recalled, set, or reset simultaneously, with one simple switching action. The whole processor 200 can therefore be quickly and easily reconfigured, thereby completely modifying the sound produced. In the preferred embodiments, the reconfiguration process takes about 10 ms.

The present invention thus enables the musician to change the sound very quickly at any point during the execution of a song, or between songs, without experiencing annoying transition disturbances.

Configurations of Effects' Controls

Schematically depicted in FIG. 4 are the four different configurations of effect controls implemented in processor 200. In FIG. 4, single lines represent analogue signals, while double lines represent digital signals.

In the configuration denominated “Type 1”, the envelope detector 350 (see FIG. 3) detects the value of the sound signal envelope in a feed-forward configuration. The envelope value is then digitised (by means of A/D converters 362, not shown in FIG. 4) and sent to one of slave processors 203₁₋ₙ. Processor 203ᵢ will use the envelope value in the parametrical digital synthesis of the lower-frequency, digital waveform, in a way that will be explained shortly. It will then send the digitally-synthesised waveform to the appropriate conditioning unit 201, which will produce the lower-frequency analogue sound-modulating waveform, used to modulate the input analogue signal (otherwise said, to apply the effect to the sound signal). Examples of “Type 1” effects are the formant or the wah-wah filters (in “envelope” mode).

“Type 2” is a configuration of the feedback type, in which the envelope value is calculated after the sound effect has been applied. The generation of the sound effect then continues as in the configuration “Type 1”. The compressor is an example of a sound effect that may use this type of configuration.

For other effects, as exemplified in configuration “Type 3”, the envelope value need not be calculated. The processor 203 generates the lower-frequency, effect modulating waveform under control of a timer 410. Examples of sound effects using this type of configuration are: the phaser, the panner, the formant or the wah-wah filters (when used in “auto” mode), the chorus, the delay, etc.

Lastly, in configuration “Type 4”, processor 203 receives as inputs both the envelope value, in a feed-forward configuration, and an impulse from a timer 410. It is also foreseen for certain effects belonging to this category that the envelope detector controls the timer 410 (e.g., the length and the start of count-down cycles). Sound effects such as the phaser, the panner, the formant or the “wah-wah” filters (when used in “envelope” mode), the chorus, the delay may be used in this configuration.

Digital Control of Analogue Effects—Principles

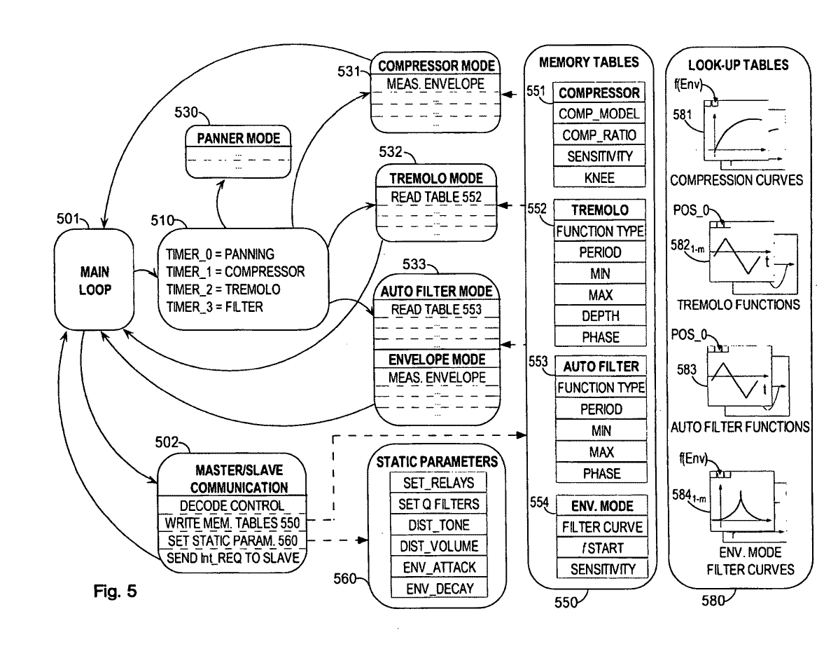

Referring again to FIG. 2, when sound processor 200 is switched on by the user, the last configuration before the machine was switched off is recalled. By way of example, let us assume that, in said configuration, all the effects are bypassed and the input signal from sources 210 goes directly to amplifier/mixer devices 260, through connections 270 and 276. Display 231 shows the initial status of the machine, with all the effects bypassed. Referring now to FIG. 5, which represents a state diagram of the sound processor 200, the processor would, in our example, be in the main idle loop 501.

By means of computer 241, built-in keyboard 242, or one of controls 220 or 252, the user may choose to switch into the signal chain one or more effects, or to recall one of the presets, stored in the sound processor 200's memory or in an external data storage (external solid state memory, computer hard or floppy disk, USB flash drive, the Internet, etc). Doing this sends a control signal—called “Peripherical_Interrupt”—from controls 220 or 252 to master processor 202. Processor 200 goes into master/slave communication state 502.

As it can be seen in FIG. 3, in the preferred embodiment master processor 202 does not directly interact with the analogue effects but simply manages the communications with displays 230 and control devices 220, 240 and 250, and sends the appropriate interrupts to slave processors 203₁₋ₙ. It is then the task of the slave processors to control the analogue effects.

This separation of tasks is important, since it is at the core of the fast and efficient operation of sound processor 200. It is however worth mentioning that the separation of tasks does not necessarily imply, nor require, a physical separation of the computational units used to perform the tasks.

As mentioned above, the slave processors only need to control a number of relatively slow processes (e.g., the synthesis of digital sound-modulating waveforms) in order to control the effects, even when the effects' parameters arc modified in real-time, and do not have to process the sound signal in any way. Aside from the already mentioned benefits of a full analogue sound signal processing, other important advantages descend directly from this fact. Since high computational power is not required from the processors used in this effect machine, costs will be reduced, along with power consumption; RISC processors are ideally suited for these tasks as they can efficiently manage a number of independent routines by virtue of their internal independent, high-precision timers and D/A, and their reduced sets of instructions. Therefore, switching into the signal chain and controlling one additional effect does not reduce the sonic quality of the effects already in use, since the computational power of the processors does not have to be shared among processes. This, on the other hand, is another drawback affecting DSP-based multi-effect processors, in which the sound effects are based on computational-heavy FFT (fast Fourier transform) or a DFT (discrete Fourier transform) performed by the DSP.

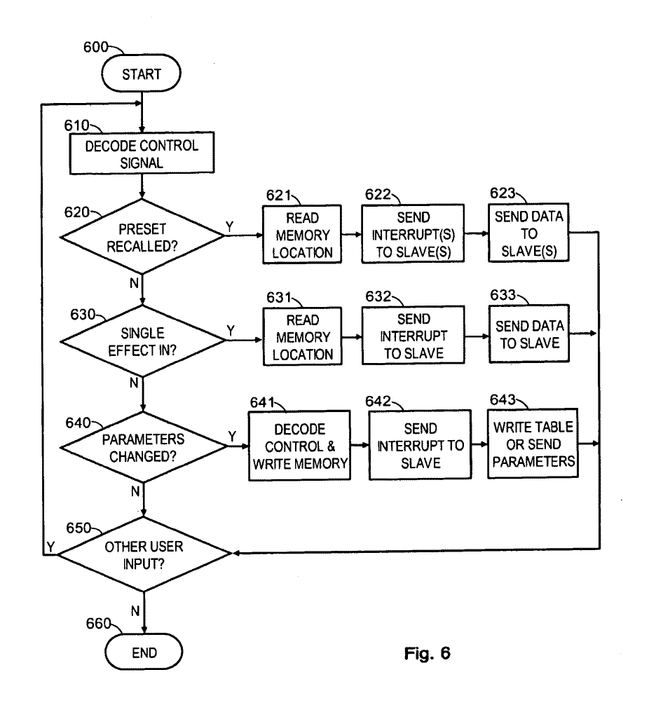

Going back now to the mode of operation, while in master/slave communication state 502, the master processor 203 performs the operations as described in the flowchart of FIG. 6.

In step 600, the processor 200 is in state “main loop” 501, and master processor 202 receives the control signal “Peripherical_Interrupt” from controls 220 or 252.

In step 610, master processor 202 decodes the instructions received in the control signal.

In step 620, if the user has imparted the instruction to recall a stored preset, the process continues with step 621.

In step 621, the control signal contains a reference to a memory location in which there is stored a pointer to a further memory location (which can again be onboard or in an external data storage linked to processor 200 via a data bus). This latter memory location contains all the parameters of a preset defining a given combination of sound effects, that is to say, the complete configuration of sound processor 200. In the preferred embodiment, these parameters are encoded in 128 bytes and include: status of all bypass relays, status of all the effects' parameters and their relative phases, the preamp gain, the parameters of the envelope detector (attack and decay), and the associations of effects' parameters with the external controls 220 for the static or dynamic control of the effects (see below). Since different effects may be controlled by different slave processors 203₁₋ₙ, a number of pointers may in fact be stored in the memory location referred by the control signal.

In step 622, master processor 202 sends an interrupt request to the slave processor(s) controlling the effects to be switched into the signal chain.

In step 623, having received the acknowledgment of the interrupt request(s) from the slave processor(s), master processor 202 sends to the appropriate slave processors 203ᵢ a mix of pointers (to memory locations containing routines and parameters) and/or parameters, which the slave processor will then use to set and control the effect(s). From this point onwards, the slave processor(s) will operate on the effects 205₁₋ₖ independently from the master processor, until another Peripherical_Interrupt is received.

In step 630, master processor 202 checks whether the user, in alternative to recalling a preset, has imparted the instruction to switch into the signal chain a single effect, by means of one of controls 220 or 240. If this is the case the routine proceeds to steps 631, 632, and 633 which are essentially equivalent to steps 621 to 623 described above, with the exception that only one slave processor may be involved. Master processor sends to the appropriate slave processor an interrupt request, in which there is a pointer to a memory location containing a routine which will instruct the slave processor to operate on the suitable relay circuits.

In step 640, master processor 202 checks whether instead of recalling a preset or switching in a sound effect, the user has imparted, by means of controls 220 or 240, the instruction to modify one or more of the effects' parameters.

If this is the case, in step 641, master processor decodes the control signal coming from controls 220/240.

In step 642, master processor 202 sends an interrupt to the appropriate slave processors 203ᵢ.

In step 643, processor 202—as appropriate, depending on the parameter—either writes the new parameters in the appropriate memory table(s) (see below), or sends the decoded new parameters directly to the slave processor concerned. Examples of such memory tables are shown in FIG. 5 (550, 560, and 580). Let us assume, for instance, that the user has changed the function used to modulate the analogue tremolo effect from “triangle” to “sine”. In such a case, master processor 202 writes in table 552 a pointer to the (programmable) look-up table (LUT) of the group 582₁₋ₘ (Tremolo functions) containing the function “sine”. Table 552 will be subsequently read by the slave processor, as it will be explained later, and as result the function “sine” will be used from that point onwards to modulate the tremolo effect.

In step 650, master processor 202 checks whether it has received another “Peripherical_Interrupt” from controls 220 and, if so, restarts the routine from step 610. If not, the machine returns in state “main loop” 501 (see FIG. 5). In this state, the main processor is waiting for external inputs, while the slave processors are independently controlling the analogue effects.

Real-Time, Dynamic Parameter Adjustment

An important feature of this invention lies in the fact that it allows the musician to dynamically vary the sound produced. He/she can achieve this by operating, continuously if desired, on one or more of the external controls 220 or 252, while playing.

Along with the types of controls 220 mentioned above with reference to the semi-static configuration of the sound processor, these external controls can take other forms that are more suitable for continuously regulating the parameters, such as sliders, pressure sensors, trackballs, multi-axis dynamic controls, foot-operable potentiometers, touchpads, and the like.

Thanks to the inventive solution for digitally controlling analogue effects described herein, the sound processor 200 is capable of dynamically tracking the user's inputs and of seamlessly and continuously adapting the sound.

In general terms—and before going into the details of the dynamic mode of operation of the control apparatus of this invention—the mechanism enabling it to be dynamically controllable is based on an automated, real-time repetition of the process previously described with reference to FIG. 5. In the preferred embodiment, this is facilitated by the following features:
1. The separation of tasks between master and slave processors: the master processor deals with the external inputs (from the users), decodes them and modifies the LUT, which will then be read by the slave processors. The slave processors drive the analogue effect by means of suitable conditioning units (341-345, FIG. 3) using the parameters stored in the LUT by the master processor;
2. The choice of an appropriate conditioning unit as interface between the slave processor and the analogue sound effect, so as to drive the analogue circuitry of the effect with the necessary dynamic range and responsiveness.

With regard to point 1 above, it is worth pointing out again that the logical separation of tasks between master and slave processors does not imply in any way a physical separation of processing capabilities in different hardware components. Master and slave processors may be implemented in a single die, within a single CPU, or carried out by a single executable software. The words “master” and “slave” are used in this description with reference to the logical separation of functions described therein.

The dynamic adjustment of effects parameters will now be described, with reference to FIG. 5. The machine state diagram in FIG. 5 depicts the operating mode of one of the slave RISC processors 203₁₋ₙ, under the control of the main RISC processor 202.

While effect-dependent, insofar as the list and the type of data written, read and/or manipulated by the processor during the controlling operation, the mechanism exemplified in FIG. 5 with reference to three specific effects—i.e., the compressor, the tremolo, and the formant filter—is virtually the same for all the effects 205_{1-K} included in processor 200. The extension of these concepts to other effects will be obvious, after reading the following paragraphs. It is based on the real-time parametrical synthesis of the lower-frequency digital waveforms referred to above, by means of programmable look-up tables (LUT). These waveforms are then applied to suitable conditioning units 341-345, which will drive the analogue effect.

The choice of the conditioning unit is also of importance and it depends on the characteristics of the analogue circuit implementing the effect to be driven. A conditioning unit may contain a low-pass filter with a cut-off frequency around 100 Hz, and a voltage amplifier which widens the voltage range of the D/A output according to the specifications of the analogue effect to be controlled.

With reference to FIG. 5, the mode of operation of generic slave processor 203, shall now be explained.

By way of non limiting example only, we shall assume that the musician is playing a song with its instrument connected to processor 200 and that she/he is making use in the sound chain of the analogue compressor. The analogue compressor may be defined by its parameters (see Table 551 of FIG. 5), which may include: compression model, compression ratio, sensitivity and knee. Other parameters may also be used to characterise the effect applied to the sound by the compressor. While the musician is performing—but not acting on controls 220—slave processor 203ᵢ is controlling the compressor effect (and/or more analogue effects 205) by repeating the control loop which will now be described.

Each one of slave processors 203₁₋ₙ features certain a number of independently controllable timers. Each timer is associated to a specific one of the effects available in the multi-effect processor 200. In alternative embodiments, some of the timers may also be shared between effects. In the example of FIG. 5, the timers of processor 203, may be associated to the loops controlling the following effects: the panner, the compressor, the tremolo, and the formant filter. The timers may be continuously and independently counting down from a predetermined value T. Alternatively, the timer may count up from 0 to a value T, or cycle upwards or downwards between any two integer values.

Every time one of the timers reaches 0 in the count-down from T, the slave processor receives an interrupt request (Timer Interrupt_REQ in FIG. 5) and performs a number of steps, as prescribed for the effect-specific routine. Examples of these routines are shown in FIG. 5 (530, 531, 532, and 533).

In keeping with our example, we will describe the case of a user making use of the compressor effect. In this case, Timer_1 is the timer performing the count-down. As the timers arc completely independent, the musician can use multiple effects associated with the same processor, possibly along with other effects controlled by other processors, without impairing the sound produced by effect processor 200. In such a scenario, all the routines performed by the slave processor(s) follow the same pattern that will be described shortly. For the sake of simplicity of the description, we will limit ourselves to the case when only one effect is being used.

Upon Timer_1 reaching 0 (or a given preset value), an interrupt request “Timer Interrupt_REQ” is sent to the slave processor. The processor moves from state 501 to state 510.

In state 510, the slave processor detects which one of the onboard timers has sent the interrupt requests and activates the corresponding routine.

In the first step of the routine, the slave processor restarts the timer (in this case Timer_1) by resetting it to the next countdown starting value. To do this, the processor loads the new countdown starting value—which may or may not have changed since the previous iteration. This is equivalent, in fact, to setting the interval until the following interrupt. The length of this interval has an impact on how quickly external control commands (e.g., user's inputs) arc translated into changes of effect's parameters, and on the granularity and definition of the digital control of the analogue effect.

In an alternative embodiment, a certain timer may be associated with two different effects—e.g., compressor and tremolo; in this case, the slave processor checks a specific bit of the interrupt request in order to determine whether the interrupt request concerns the compressor or the tremolo effect.

Having started the next countdown, the processor moves to state 532 Compressor Mode and performs the following routine:
1. It reads the value Env of the signal envelope, as measured by the envelope detector 350 (see FIG. 3);
2. it reads the current compressor parameters from Table 551;
3. it reads the value Y=f(Env) from one of the programmable look-up tables 881₁₋ₘ, where f(Env) is the model function of the compression curve, as a function of the measured signal envelope value;
4. it normalises the value Y using the actual current compression parameters, e.g., Comp_ratio, Sensitivity, and Knee, read from table 551, thereby generating the value Y′.

This value Y′ may now be sent to the appropriate conditioning unit 201 which interfaces the slave processor with the effect. In this exemplary embodiment, the effect is the compressor and the conditioning unit a D/A driving a transistor and a low-pass filter (element 342 in FIG. 3).

At the end of the routine, the slave processor returns to state Main Loop 501, waiting for the next interrupt request.

Meanwhile, the master processor 202 is monitoring controls 220 and 250, and external programming/interface means 240. By way of non limiting example only, it will be assumed in the following that the user wants to modify continuously and in real-time, while playing, the compression sensitivity of the compressor/limiter. To do so, the user may operate on one of the controls 220 described above, or on controls 252.

Controls 220 and 252 can be assigned—by means of programming means 240—to control any one or any combination of parameters of the effects available in the sound processor 200, or of effects connected thereto (using, for instance, the MIDI control chain).

By operating on a continuously-operable control (such as a foot pedal or foot controller, a slider, a pressure sensor, and the like), the user can adapt the compression ratio according to the part of the song s/he is playing. Mechanically-applied user inputs are encoded and sent by controls 220 to master processor 202 using, for instance, one, or more, of protocols 273 of FIG. 2 (e.g., MIDI, USB, I²B, serial transmission protocols, Wi-Fi®, Wireless USB or WUSB, other wired or wireless communication protocols). The specific protocol used is anyway not essential for carrying out the present invention.

In this case, while in state Main Loop 501, master processor 202 receives a Peripherical_Interrupt request from controls 220. This Peripherical_Interrupt request causes the master processor 202 to enter into Master/Slave Communication state 502, independently of the state of slave processors 203. Master processor 202 performs the following operations (as described above with reference to FIG. 6):
1. It decodes the control (e.g., the request of modifying the compressor curve);
2. it calculates and writes in the appropriate memory table (e.g., the Compressor table 551, which is stored, for instance, in a programmable memory inside processor 200) the parameters defining the new compressor curve;
3. it sets the necessary static parameters (e.g., the attack and decay of the envelope detector, sec 560), if such changes to the static parameters are required.

At the next occurrence of a Timer Interrupt_REQ from Timer_1, as described above, the slave processor responsible for controlling the analogue compressor effect will find the new parameters in the appropriate memory table (551). The new parameters (e.g., the new compression ratio) will then be used to drive the compression effect.

Due to the high speed at which the processors operates and to the short timer cycles, user inputs can be received, decoded and used to drive the effect in a continuous, real-time fashion. It should be clear at this point that the parameter T (countdown starting value) sets the minimum refresh/update time of the parameters of the effect associated to it, and it is important in two ways: on the one hand, it sets the time it takes to the processor to react to a variation in the input musical signal (as measured by the envelope detector, in this case) and to adapt the compression (or any other sound effect) applied; on the other hand, it sets the minimum time between two user control inputs, which the effect processor is able to react and adapt to. By choosing T small enough (i.e., smaller than the time constant of the envelope detector in this case), the effect's parameters can be updated in a time-discrete fashion but the change will be perceived as a continuum by the human ear. The effect obtained is that of a real-time, continuous response of the effect to the variations in the input signal, in truly analogue fashion, as well as that of a real-time, continuous controllability of the effect's parameters by the user.

The same mechanism describe here above is therefore at the heart of the real-time parametrical synthesis of the modulating waveforms used to control analogue effects. The efficiency of the process is thus greatly increased by storing, for each effect, a number of model functions (e.g., the model compression curves), which are then dynamically and parametrically modified and adapted to the user inputs. The stored model functions may, in turn, be created, modified and stored in tables 580 by the user, by means of programming means 240. In this way, the user can completely and dynamically adapt the sound created by the analogue effects 205 and obtain a truly unique and personalised sound.

### Second Example

### Formant Filters

As a second example, again with reference to FIG. 5, we will describe the case of a user making use of the formant filter effect. In this example, Timer_3 is the timer performing the count-down. The formant filters of the preferred embodiments of processor 200 feature various operating modes: “auto”, “fixed” or “manual” and “envelope” mode. As explained earlier with reference to FIG. 4, in “auto” mode the formant filter operates like an effect of the type 3 (that is, controlled by a timer 410), in envelope mode like an effect of the type 4 (that is, timer 410 is controlled by the signal produced by the envelope detector 350). The mode is chosen by the user and, although alternative, the two operating modes will be described in parallel here. In embodiments of the processor 200 featuring more than one formant filter, the two—or more—filters can operate independently, in either “auto” or “envelope” mode.

Every time Timer_3 reaches 0, it sends an interrupt request—Timer Interrupt_REQ—to the slave processor. The processor moves from state 501 to state 510.

In state 510, the slave processor checks which one of the onboard timers has sent the interrupt requests and activates the corresponding routine.

In the first step of the routine, the slave processor resets the timer (in this case Timer_3) to the next countdown starting value. To do this, the processor loads the new countdown starting value—which may or may not have changed since the previous iteration. In both “auto” and “envelope” modes the countdown value T can be been chosen and modified by the user and plays the same role described earlier in the case of the compressor.

Having started the next countdown, the processor moves to state 533, choosing either Auto Filter Mode or Envelope Mode, depending on the user-selected settings for processor 200, and performs one of the following routines:

Auto Mode:
1. It reads the parameters of the Auto Filter function from look-up table 553 (Function Type, to address the correct look-up table 583; period, min and max, and starting phase of the model function selected);
2. it reads the value of the pointer Pos_0 of the selected model function (e.g., a triangle) from look-up table 583;
3. it updates the position pointed by said pointer Pos_0 by one unit (i.e., to the next location of the look-up table, to be read in the next cycle);
4. it normalises the value Pos_0 using the parameters read in step a. The model function is thus parametrically scaled to the desired value Y′.

Envelope Mode:
1. It reads the value Env of the signal envelope, as measured by the envelope detector 350 (see FIG. 3);
2. it reads the current filter parameters from look-up table 554 (‘f start’, the starting frequency of the frequency sweep, and the sensitivity);
3. it reads the value Y=f(Env) in one of the programmable look-up tables 584₁₋ₘ, which store the model of the filter frequency-sweeping functions used by the formant (or “wah-wah”) filter(s);
4. it normalises the value Y by applying the parameters ‘f start’ and ‘sensitivity’ read from table 554 to the model curve 584, generating the value Y′.

The value Y′ calculated in step d of either routine is then sent to the appropriate conditioning unit 201 (FIG. 3) which interfaces the slave processor with the formant filter effect. In this example the effect is a formant filter and the conditioning unit used a D/A driving a transistor and a low-pass filter.

As in the previous example, at the end of the routine, the slave processor returns to state Main Loop 501, waiting for the next interrupt request.

Again as in the previous example, master processor 202 monitors the controls 220 and 250, and programming means 240, to detect user's instruction aimed at adjusting in real-time the parameters of the filters stored in tables 553, for a filter in “auto” mode, or 554, for a filter in “envelope” mode. The routine, starting with the processor 200 entering into state 502, is essentially identical to the one described above with reference to the compressor effect, with obvious adaptations due to the different parameters of the filter effect.

Envelope Detection.

We shall refer now once again to FIG. 3 to explain the importance of controlling envelope detector 350 by means of processors 202 and 203₁₋ₙ. The envelope detector is an important integral part of many sound effects. It is used to recover the envelope of the sound signal and control the sound effect parameters.

The digitally controlled envelope detector 350 and the presence of look-up tables 362, enables the method and apparatus proposed in this invention to achieve two advantages hitherto not available to analogue effects.

One advantage lies in the fact that thanks to the look-up tables, any function can be used to control an effect's parameter as a function of the envelope value detected. In traditional analogically-controlled effects, once the detected envelope value has been fed to the effect-modulating circuit (i.e., the analogue circuitry generating the lower-frequency modulating waveform), the process has to contend with the limitations of the analogue circuitry, with regard to the types and characteristics of effect-controlling waveforms that can be generated. Only a limited number of periodic waveforms can be generated analogically (typically sine, triangle and square waves). A further limitation lies in that their total energy, integrated over one period, must be 0. All these limitations in turn restrict the number of ways in which the sound signal can be modulated and, therefore, the creative scope of musicians. When, on the other hand, the modulating waveforms are digitally synthesised by means of a programmable look-up table, as it is the case in the present invention, the above limitations are removed. This applies, of course, also to effects that are not envelope driven, such as those of the Type 3, in FIG. 4.

Just as importantly, look-up tables are used in the processor of this invention to compensate for psychoacoustic non-linear effects.

One example of this can be seen in the formant filters (or “wah-wah” filters). Typically, the frequency sweep Δfreq (the effect parameter or, more generally, the modulating function w of an effect) of analogue formant, or “wah-wah”, filters is controlled by the following equation:

Δfreq=a·ΔEnv+b, (Eq. 1)

where a and b are constants and ΔEnv is the variation of the signal envelope. ΔEnv is related to the variation in energy of the input signal (in the case of an electric guitar, for instance, it could be quantitatively explained as “how hard” the guitar is being played).

Two problems come into play at this point, when a linear equation such as the one above is used. The linear equation does not allow the frequency sweep to vary as a function of the variation in the envelope. It would be, however, highly desirable in order to increase the expressive possibilities, if the frequency sweep of the filter was a function ƒ of the envelope variation:

Δfreq=a·ƒ(ΔEnv)+b, (Eq. 2)

This could be easily understood considering that with the modulating function of equation 2 a musician could expressively control the frequency sweep (i.e., the filter action) by controlling the envelope variation (for instance, by controlling how “hard” he/she plays the instrument). It is therefore desirable that the response of the filter could somehow reflect the musician's expression. Unfortunately, analogue control circuitry is very limited in the type of functions available and in the case with which they can be produced.

While it is, for instance, feasible to produce a natural logarithmic function (ln) using analogue circuitry, so that equation 2 could be written as:

Δfreq=a·ln(ΔEnv)+b, (Eq. 3)

this is still very complicated to obtain and the actual function generated can only approximate a true logarithmic function in a very limited part of the input signal range.

Moreover, the human car is linearly responsive to a log₁₀ (base 10 logarithmic) function rather than a ln (natural logarithmic) function of the frequency variation (an octave). The log₁₀ function is all but impossible to obtain using analogue control circuitry.

Using look-up tables 362 and the controlling method described above with reference to FIG. 5, any functions of the envelope value, or of the envelope variation (as detected by the envelope detector 350 and digitised by one of A/D converters 361) can be used by the slave processor 203 to drive the analogue effect. In fact, any function at all can be used to this effect.

It is therefore possible, in the exemplary case of the filter, to realise the modulating function:

Δfreq=a·log₁₀(ΔEnv)+b, (Eq. 4)

as well as any other function of the envelope variation, according to equation 2.

It is also possible, and indeed desirable, to obtain a point-by-point definition of the parameter-controlling function by modelling or sampling existing analogue effects, of which a musician might be particularly fond. This point-by-point definition can be stored in look-up tables 362 or 580 and used to control the parameter(s) of a given effect or combination of effects.

For instance, a vintage analogue compressor effect employing a specific type of vacuum tubes, or transistors, or opto-resistors can be modelled—for instance by measuring its transfer function—and/or sampled, and its model can be stored in a look-up table or other suitable data storage means. This look-up table now stores a point-by-point definition of the ƒ(ΔEnv) (or ƒ(Env), the instantaneous value of the signal envelope rather than its variation, as it is more appropriate for a compressor effect) mentioned above. By using the look-up table thus created to control the compressor parameters, the processor 200 is able to faithfully reproduce the sound of the sampled vintage effect.

The present invention, by means of look-up tables 362 or 580, removes all the limitations traditionally affecting analogue effects, compensates for any unwanted non-linear and/or psychoacoustic effect and, in short, gives the musician even more control upon the sound produced.

Those of ordinary skill in this art will understand that the use of look-up tables is just one example of how to apply a transformation to detected envelope values. Alternative means, such as—but not limited to—a processor, software program(s), firmware program(s), hardware description language (HDL), or any combination of these means could be used. Further, discrete logic, field-programmable gate arrays (FPGAs), application specific integrated circuits (ASICs), and other suitable means could also be used.

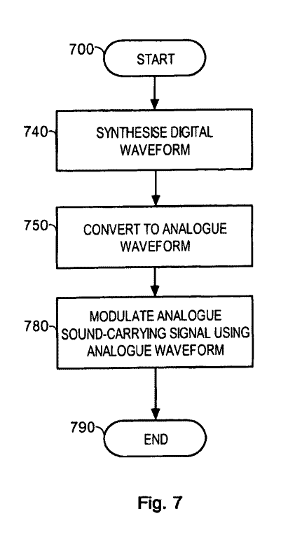

FIG. 7 is a flowchart illustrating a method for digitally-controlling, continuously and in real-time at least one analogue sound effect, according to an exemplary embodiment of the present invention.

In step 740, the processor 203 synthesise a digital waveform as described above with reference to FIG. 5.

In step 750, the conditioning unit 201 converts the digital waveform into an analogue waveform.

In step 780, the analogue (sound-modulating) waveform is used by analogue effect 205 to modulate the sound-carrying signal at its input, thereby applying the sound effect.

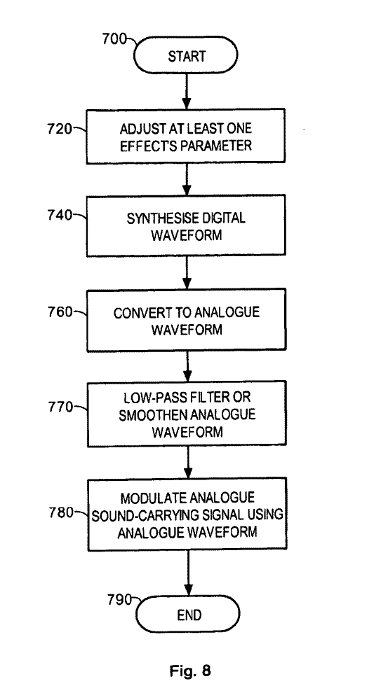

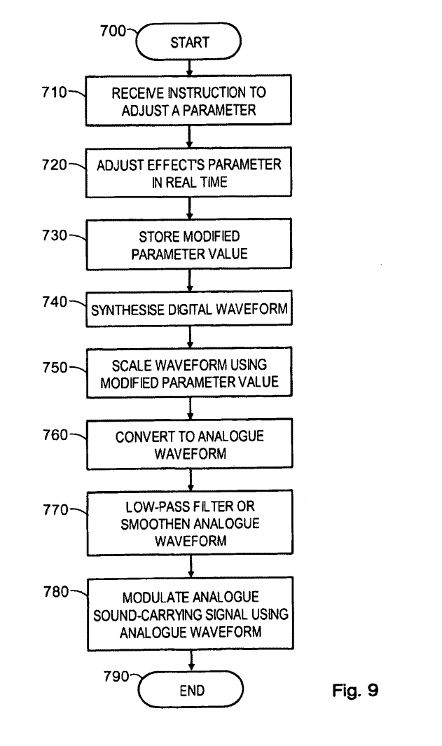

As depicted in FIG. 8 and FIG. 9, the method of FIG. 7 may further include step 720, in which the processor 203 adjust or modifies at least one parameter of the analogue sound effect to be applied, prior to synthesising the digital waveform. It may also further include step 770, in which low-pass filtering and interpolating (smoothening) is applied to the analogue waveform, thereby producing a low-pass filtered and interpolated (smoothened) analogue waveform

As depicted in FIG. 9, the method may further include step 710, in which processors 202-203 receive an instruction to modify at least one parameter of the analogue sound effect to be applied. It may also further include step 730, in which the modified value of the parameter is stored, prior to synthesising the digital function in a table in an on-board or external memory or storage device. It may further include step 750, in which the digital waveform is scaled using the modified parameter.

Although a few exemplary embodiments of the present invention have been shown and described, it will be appreciated by those skilled in the art that electrical, mechanical, structural and logical changes may be made to the embodiments of the above description without departing from the scope of the present invention as defined in the appended claims and their equivalents.

1. Apparatus for digitally controlling, continuously and in real-time, at least one analogue sound effect (205) applied to an analogue sound-carrying signal (270), comprising:
a) Digital means (202, 203) adapted to synthesise a digital waveform;
b) Conditioning unit means (201) arranged to convert said digital waveform into an analogue waveform;
c) Modulating means (205) arranged to receive said analogue waveform and an analogue sound-carrying signal (270), said means (205) being adapted to modulate said analogue sound-carrying signal (270) using said analogue waveform.

2. Apparatus according to claim 1, wherein said digital means (202, 203) are further adapted to control and adjust in real-time at least one parameter of at least one said analogue sound effect (205).

3. Apparatus according to claim 2, further comprising control means (220, 250) adapted to receive an instruction to vary in real-time at least one parameter of at least one said analogue sound effect (205), said control means (220, 250) being connected (273, 274) to said digital means (202, 203) and further adapted to transmit said instruction to said digital means (202, 203).

4. Apparatus according to claim 3, wherein said digital means (202, 203) are further adapted, upon receiving said instruction, to:
a) modify the value of said at least one parameter;
b) store the modified value of said at least one parameter;
c) synthesise said digital waveform scaled by said at least one modified parameter.

5. Apparatus according to claim 4, further comprising at least one digital-to-analogue converter (342) and at least one opto-resistor (343), wherein said digital means (202, 203) are adapted to control the emitter diode forward current of said opto-resistor, thereby adjusting the value of said at least one parameter.

6. Apparatus according to claim 4 or 5, further connected to control means (220, 240, 250), adapted to enable the user to send to said digital control means (202, 203) an instruction to change the value of said at least one parameter.

7. Apparatus according to any of the preceding claims further comprising at least one envelope detector (350) adapted to detect the envelope of the analogue sound-carrying signal.

8. Apparatus according to claim 7 wherein said digital means (202, 203) are further adapted to control in real-time at least one parameter of said at least one analogue sound effect (205) by computing and using a parameter-controlling function w of the instantaneous envelope value detected by said at least one envelope detector (350).

9. Apparatus according claim 8, wherein said parameter-controlling function w of the instantaneous envelope value is in the form:
w=a·ƒ(Env)+b,
where a and b are constants, Env is the value of the amplitude, and ƒ is any mathematical function.

10. Apparatus according to claim 8, wherein said parameter-controlling function w is stored point-by-point in a look-up table as a function of the instantaneous value of the envelope.

11. Apparatus according to claim 10, wherein said analogue effect (205) is a compressor effect and said parameter-controlling function w is retrieved from a model, or by measuring the transfer function, of an analogue compressor effect unit using at least one of vacuum tubes, transistors, or opto-resistors.

12. Apparatus according to claim 10, wherein said analogue effect (205) is a formant filter effect and wherein said parameter-controlling function w defines point-by-point a non-linear transformation between the output of the envelope detector and the frequency of the filter.

13. Apparatus according to claims 7 to 12, wherein said envelope detector (350) is connected so as to detect the envelope of said analogue sound-carrying signal before said signal is modulated by said at least one analogue sound effect (205).

14. Apparatus according to claims 7 to 12, wherein said envelope detector (350) is connected so as to detect the envelope of said analogue sound-carrying signal after said signal has been modulated by said at least one analogue sound effect (205).

15. Apparatus according to claims 7 to 12, further comprising two or more envelope detecting means (350).

16. Apparatus according to claims 1 to 15, wherein said digital means (202, 203) include at least two or more RISC processors connected in master-slave configuration, wherein one of the processors is adapted to be the master processor.

17. Apparatus according to any of the preceding claims wherein said at least one analogue sound effect (205) is selected from the list comprising: compressor, distortion, phaser, pre-amplifier, tremolo, panner, formant filter, chorus, delay, and flanger.

18. Apparatus according to claim 17 comprising two or more effects from said list, and wherein said two or more effects (205) are connected in cascade.

19. Apparatus according to claim 18, wherein said digital means (202, 203) are further adapted to synchronise and control the relative phases of said two or more digital waveforms.

20. Apparatus according to any of the preceding claims wherein said digital means (202, 203) are further connected to data storage means (362) in which at least one look-up table is stored, said at least one look-up table (580) containing a point-by-point definition of said digital waveform.

21. Apparatus according to claim 20, wherein said digital means (202, 203) are adapted to synthesise said digital waveform by reading the values of said waveform from said look-up table (580).

22. Apparatus according to claim 21, wherein said digital means (202, 203) are further connected to at least one timer (410), which is adapted to instruct said digital means (202, 203), at the end of each counting cycle of period T of said at least one timer (410), to read one value from said at least one look-up table (580).

23. Apparatus according to claim 23, wherein said timer (410) is arranged to have the period T of said counting cycle modified by said digital means (202, 203) or by the user.

24. Apparatus according to any of the preceding claims wherein said conditioning unit means (201) comprise means (341, 342, 343, 344, 345) adapted to accept a digital signal at its input, to perform low-pass filtering or smoothening of said analogue waveform, and to output an analogue signal proportional to the input digital signal.

25. Apparatus according to claim 24, wherein said means adapted to convert a digital signal into an analogue signal are selected from the list comprising: digital potentiometer (341) and digital-to-analogue converter (342, 343, 345).

26. Apparatus according to claim 25, wherein the output of the digital-to-analogue converter is connected to the input of one of: an opto-resistor (343), a voltage controlled oscillator (344), or a low-pass filter (342).

27. Multieffect sound processor (200) for use with electrical or electrified instruments containing an apparatus according to claims 1 to 26.

28. Multieffect sound processor (200) according to claim 27, further comprising wired or wireless data communications busses (272) adapted to enable downloading of said at least one look-up table into said storage means (362) and to enable uploading of data from said storage means (362) into programming and upgrading means (240).

29. Multieffect sound processor (200) according to claim 27 or 28 further comprising wired or wireless data communication busses (273, 274) adapted to download into data storage means of said multieffect processor (200) and upload from data storage means of said multieffect processor (200) effects' parameters and complete processor's configuration presets.

30. Method for digitally controlling, continuously and in real-time, at least one analogue sound effect applied to an analogue sound-carrying signal, comprising the steps of:
a) synthesising (740) at least one digital waveform;
b) converting (750) said at least one digital waveform into at least one analogue waveform;
c) modulating (780) an analogue sound-carrying signal using said at least one analogue waveform.

31. Method according to claim 30, wherein said step of synthesising (740) further comprises the steps of:
a1) adjusting (720) at least one parameter of at least one said analogue sound effect
b1) low-pass filtering or smoothening (770) said analogue waveform

32. Method according to claim 31, further comprising the step of receiving (710) from a control source an instruction to change in real-time at least one parameter of at least one said analogue sound effect.

33. Method according to claim 32, wherein the step of synthesising (740) further comprises the steps, upon receiving said instruction, of:
a1) adjusting (720) the value of said at least one parameter
a2) storing (730) the modified value of said at least one parameter;
a3) synthesising said digital waveform and scaling (750) it by said at least one modified parameter.

34. Method according to claim 33, further comprising controlling the emitter diode forward current of an opto-resistor connected to the output of a digital-to-analogue converter, thereby adjusting the value of said at least one parameter.

35. Method according to claim 33 or 34, further comprising the step of receiving from a user an instruction to change the value of said at least one parameter.

36. Method according to claims 30 to 35, further comprising the step of detecting the envelope of the analogue sound-carrying signal.

37. Method according to claim 36, further comprising the steps of controlling in real-time at least one parameter of said at least one analogue sound effect by computing and using a parameter-controlling function w of the detected envelope amplitude value.

38. Method according claim 37, further comprising the step of computing said parameter-controlling function w of the detected envelope value by computing:
w=a·ƒ(Env)+b,
where a and b are constants, Env is the amplitude of the envelope, and ƒ is any mathematical function.

39. Method according to claim 37, further comprising the step of retrieving said parameter-controlling function w point-by-point from a look-up table as a function of the amplitude value of the envelope of the analogue electrical sound-carrying signal.

40. Method according to claim 39, further comprising the step of retrieving said parameter-controlling function w from a model, or by measuring the transfer function, of an analogue compressor effect unit using at least one of vacuum tubes, transistors, or opto-resistors.

41. Method according to claim 39, further comprising the step of defining said parameter-controlling function w point-by-point as a non-linear transformation between the output of the envelope detector and the frequency of the filter.

42. Method according to claims 36 to 41, further comprising the steps of detecting the envelope of the analogue sound-carrying signal before said signal is modulated by said at least one analogue sound effect.

43. Method according to claims 36 to 41, further comprising the steps of detecting the envelope of the analogue electrical sound-carrying signal after said signal has been modulated by said at least one analogue sound effect.

44. Method according to claims 30 to 41, further comprising the steps of synchronising and controlling the relative phases of two or more digital waveform.

45. Method according to claims 30 to 44, wherein the step of synthesising a digital waveform (740) further comprises the step of reading a point-by-point definition of said waveform from look-up table stored in memory.

46. Method according to claim 45 further comprising the step of generating an instruction to read one value from said look-up table at the end of each counting cycle of period T of a timer.

47. Method according to claim 46 further comprising the step of changing the period T of the counting cycle.
